(19) United States
(12) Patent Application Publication
(10) Pub. No.: US 2026/0319035 A1
(43) Pub. Date: Oct. 15, 2026

(54) BIRDCAGE COIL USING RF SHIELDING AND END RING RESONANCE FOR DECOUPLING

(71) Applicant: Quality Electrodynamics, LLC, Mayfield Village, OH (US)

(72) Inventors: Xiaoyu Yang, Indiana, PA (US); Tsinghua Zheng, Chesterland, OH (US); Matthew Finnerty, University Heights, OH (US); Mike Alflen, Twinsburg, OH (US)

(21) Appl. No.: 19/632,686

(22) Filed: Mar. 30, 2026

Related U.S. Application Data
(60) Provisional application No. 63/787,138, filed on Apr. 11, 2025.

(51) Int. Cl. G01R 33/34; G01R 33/36; G01R 33/422

(52) U.S. Cl. CPC G01R 33/34076; G01R 33/365; G01R 33/422

(57) ABSTRACT

The present disclosure relates to a magnetic resonance imaging (MRI) radio frequency (RF) coil that includes a birdcage coil using RF shielding and end ring resonance for decoupling. The birdcage coil comprises a first end ring, a second end ring, and a plurality of rungs extending from the first end ring to the second end ring. A first RF shield borders the first end ring. A first circuit branch is electrically coupled from the first RF shield to the first end ring and includes a first switch component. A second circuit branch is electrically coupled from the first RF shield to the first end ring. The first end ring, the first RF shield, the first circuit branch, and the second circuit branch form a first resonant decoupling coil configured to selectively resonate at a working frequency of the birdcage coil to decouple the birdcage coil.

### REFERENCE TO RELATED APPLICATION

This Application claims the benefit of U.S. Provisional Application No. 63/787,138, filed on Apr. 11, 2025, the contents of which are incorporated herein by reference in their entirety.

### BACKGROUND

Magnetic resonance imaging (MRI) involves the transmission and receipt of radio frequency (RF) energy. RF energy may be transmitted by an RF coil to create a B₁ field that rotates a net magnetization. Further, resulting magnetic resonance (MR) signals may be received by an RF coil to detect transverse magnetization. Thus, RF coils may be transmit (Tx) coils, receive (Rx) coils, or transmit and receive (Tx/Rx) coils.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a flattened view of some embodiments of a magnetic resonance imaging (MRI) radio frequency (RF) coil comprising a birdcage coil employing RF shielding and end ring resonance for decoupling.

FIGS. 2A and 2B illustrate flattened views of some embodiments of the MRI RF coil of FIG. 1 while the birdcage coil is respectively enabled (e.g., resonant) and disabled (e.g., decoupled).

FIG. 3 illustrates an axial view of some embodiments of the MRI RF coil of FIG. 1.

FIG. 4 illustrates a perspective view of some embodiments of the MRI RF coil of FIG. 3.

FIG. 5 illustrates an axial view of some alternative embodiments of the MRI RF coil of FIG. 1 in which the RF shield has a greater diameter than the birdcage coil.

FIGS. 6A-6C illustrate perspective views of some embodiments of the MRI RF coil of FIG. 5.

FIG. 7 illustrates an axial view of some alternative embodiments of the MRI RF coil of FIG. 1 in which the RF shield has a lesser diameter than the birdcage coil.

FIG. 8 illustrates a perspective view of some embodiments of the MRI RF coil of FIG. 7.

FIG. 9 illustrates a flattened view of some alternative embodiments of the MRI RF coil of FIG. 1 in which the birdcage coil is a low pass birdcage coil.

FIG. 10 illustrates a flattened view of some alternative embodiments of the MRI RF coil of FIG. 1 in which the birdcage coil is a band pass birdcage coil.

FIG. 11 illustrates a flattened view of some embodiments of the MRI RF coil of FIG. 1 in which the plurality of switch components comprise individual PIN diodes and the plurality of reactive branch components comprise individual branch inductors.

FIG. 12 illustrates a flattened view of some alternative embodiments of the MRI RF coil of FIG. 11 in which the MRI RF coil has fewer switch components.

FIG. 13 illustrates a flattened view of some alternative embodiments of the MRI RF coil of FIG. 11 in which circuit branches are offset from rungs of the birdcage coil.

FIG. 14 illustrates a flattened view of some alternative embodiments of the MRI RF coil of FIG. 11 with decoupling in multiple directions.

FIG. 15 illustrates a flattened view of some alternative embodiments of the MRI RF coil of FIG. 14 in which the MRI RF coil comprises an additional RF shield.

FIG. 16 illustrates a perspective view of some embodiments of the MRI RF coil of FIG. 15.

FIG. 17 illustrates a flattened view of some alternative embodiments of the MRI RF coil of FIG. 15 in which the MRI RF coil has fewer switch components.

FIG. 18 illustrates a flattened view of some alternative embodiments of the MRI RF coil of FIG. 14 in which the MRI RF coil comprises an additional RF shield and decoupling in multiple directions at each RF shield.

FIG. 19 illustrates a flattened view of some alternative embodiments of the MRI RF coil of FIG. 18 in which circuit branches at the additional RF shield are offset from circuit branches at the RF shield.

FIG. 20 illustrates a flattened view of some alternative embodiments of the MRI RF coil of FIG. 11 in which the MRI RF coil comprises anti-series diodes as switch components.

FIG. 21 illustrates a flattened view of some alternative embodiments of the MRI RF coil of FIG. 11 in which the MRI RF coil comprises a resonant switch component.

FIG. 22 illustrates a flattened view of some embodiments of the MRI RF coil of FIG. 11 in which the MRI RF coil comprises a matching circuit and a preamplifier.

FIG. 23 illustrates a flattened view of some alternative embodiments of the MRI RF coil of FIG. 22 in which the preamplifier is omitted.

FIGS. 24A and 24B illustrate various diagrams of some embodiments of an MRI system comprising an MRI RF coil comprising a birdcage coil employing RF shielding and end ring resonance for decoupling.

FIG. 25 illustrates a diagram of some alternative embodiments of the MRI system of FIGS. 24A and 24B in which the MRI system comprises a transmit/receive (T/R) switch.

FIG. 26 illustrates a block diagram of some embodiments of a method for performing MRI using an MRI RF coil comprising a birdcage coil employing RF shielding and end ring resonance for decoupling.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purposes of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to one or more other elements or features as illustrated in the figures. The spatially relative terms are intended to encompass different orientations of the device in use or operation in addition to the orientation depicted in the figures. The apparatus may be otherwise oriented (e.g., rotated 90 degrees or at other orientations), and the spatially relative descriptors used herein may likewise be interpreted accordingly.

The birdcage coil has been used as the built-in whole-body coil (WBC) in horizontal magnetic resonance imaging (MRI) systems since its inception. The birdcage coil has three types, depending on how capacitors are positioned on the end rings, on the rungs, or on both. These types are high pass, low pass, and band pass. For all three types, the uniform mode of the birdcage coil is typically tuned to the working frequency (e.g., the Larmor frequency) because MRI depends on a uniform transmit (Tx) B₁+field. To achieve this, the non-uniform mode frequencies are configured sufficiently far from the working frequency so that their contributions at the working frequency are negligible and the uniform mode is dominant.

When the birdcage coil is not used to detect signals in a receive (Rx) mode, it is typically decoupled (e.g., detuned). Non-limiting examples of this configuration include the WBC and local birdcage transmit coils used with phased array Rx coils in head, knee, and hand/wrist coil assemblies or other suitable coil assemblies.

A method of decoupling the birdcage coil is to place a PIN diode on each rung of the birdcage coil. Further, in some cases, PIN diodes are also placed on the end rings of the birdcage coil to prevent the end rings from resonating. During operation, the PIN diodes control the state of the birdcage coil. In the Tx mode, the PIN diodes are forward-biased and present low impedances, thereby allowing coil current to flow and enabling the birdcage coil. In the Rx mode, if the birdcage coil is not used as the Rx coil (e.g., a separate Rx coil is used for receiving), the PIN diodes are reverse-biased and present high impedances. Substantially no current flows in the birdcage coil, and the birdcage coil is decoupled.

Besides the Tx mode and the Rx mode, there is a safety-related mode for local birdcage transmit coils. This mode is referred to as an unplugged mode (e.g., the coil is disconnected from the MRI system and left inside the MRI system due to human error). In the unplugged mode, the coil may be exposed to a high-power B₁ field from the WBC without any bias (e.g., forward or reverse) applied to its PIN diodes. Without bias, the behavior of the PIN diodes is unpredictable. The birdcage coil may remain in resonance, allowing large induced RF currents to flow, which can cause excessive heating and pose a safety risk. Alternatively, the PIN diodes may present high impedance and the birdcage coil may be decoupled.

Because there is no power supply in the unplugged mode, anti-series PIN diodes may be used to replace PIN diodes as unbiased high-impedance switches. Anti-series diodes are at least two diodes placed in series with opposite polarities. Without any direct current (DC) bias, any direction of radio frequency (RF) current through the anti-series diodes encounters at least one reverse-biased diode, thereby presenting a high impedance.

Birdcage coils are often used with RF shields. For example, many WBCs include an RF shield positioned between the system gradient coils and the birdcage coil. For local birdcage coils, various RF shield configurations may be used depending on the application.

One type of RF shield is a conductive tube surrounding the birdcage coil. Another type uses conductive shielding rings positioned adjacent to the birdcage end rings. The shielding rings may be positioned outside of the birdcage coil at approximately the same diameter as the birdcage coil, on top of the end rings at a slightly larger diameter, or below the end rings at a slightly smaller diameter. Yet another type extends the shielding ring concept by including additional shielding elements along the birdcage rungs, forming a birdcage-shaped conductive shield outside of the birdcage coil that provides shielding for both the end rings and the rungs.

A challenge with birdcage coils as described above is that many PIN diodes are employed for decoupling. For example, for a 16-rung birdcage coil, at least 16 PIN diodes are used on all rungs. If both end rings are also decoupled, another two PIN diodes are used. This amounts to a large number of PIN diodes. Further, if a birdcage coil is a local Tx/Rx coil (e.g., used in both the Tx mode and the Rx mode), then each PIN diode is replaced with a set of anti-series diodes. The number of PIN diodes may increase to 36.

An additional challenge is that many diodes not only increase the cost of the coil but also decrease the birdcage coil efficiency. PIN diodes in an ON state are not perfect electrical shorts and have resistances. For example, each diode may have a resistance of about 0.1 to about 0.5 Ohm depending on the application. These resistances seem small but are not negligible when they are part of a high-Q resonant circuit. A typical birdcage coil includes capacitors, conductive (e.g., copper) traces, and PIN diodes in resonance. Capacitors are considered almost lossless, and loss from the conductive traces is small. Thus, PIN diode loss may be considered significant. Further, this PIN diode loss may become more serious at lower frequencies because the coil loss, including PIN diode loss, is the dominant factor of the coil signal-to-noise ratio (SNR).

The present disclosure is directed toward a method for decoupling a birdcage coil using RF shield and end ring resonance, as well as an MRI RF coil comprising the birdcage coil and an MRI system comprising the MRI RF coil. As seen hereafter, the method leads to significantly fewer diodes and significantly less diode loss.

In some embodiments, the MRI RF coil comprises a birdcage coil, a first RF shield bordering a first end ring of the birdcage coil, a first circuit branch electrically coupled from the first RF shield to the first end ring and comprising a first switch component, and a second circuit branch electrically coupled from the first RF shield to the first end ring. The first end ring, the first RF shield, the first circuit branch, and the second circuit branch form a shield/end ring coil. The shield/end ring coil shares a reactive component (e.g., a capacitance and/or inductance) with the birdcage coil (e.g., via the first end ring) and is configured to selectively resonate at the same frequency (e.g., a Larmor frequency) as the birdcage coil.

In a first state, the first switch component enables resonance of the shield/end ring coil at the working frequency. This creates a high impedance along the first end ring that blocks current in the birdcage coil and further blocks current from passing between the shield/end ring coil and the birdcage coil, thereby decoupling the birdcage coil. In a second state, the first switch component disables resonance of the shield/end ring coil and electrically isolates the shield/end ring from the first end ring. Hence, the birdcage coil resonates at the working frequency.

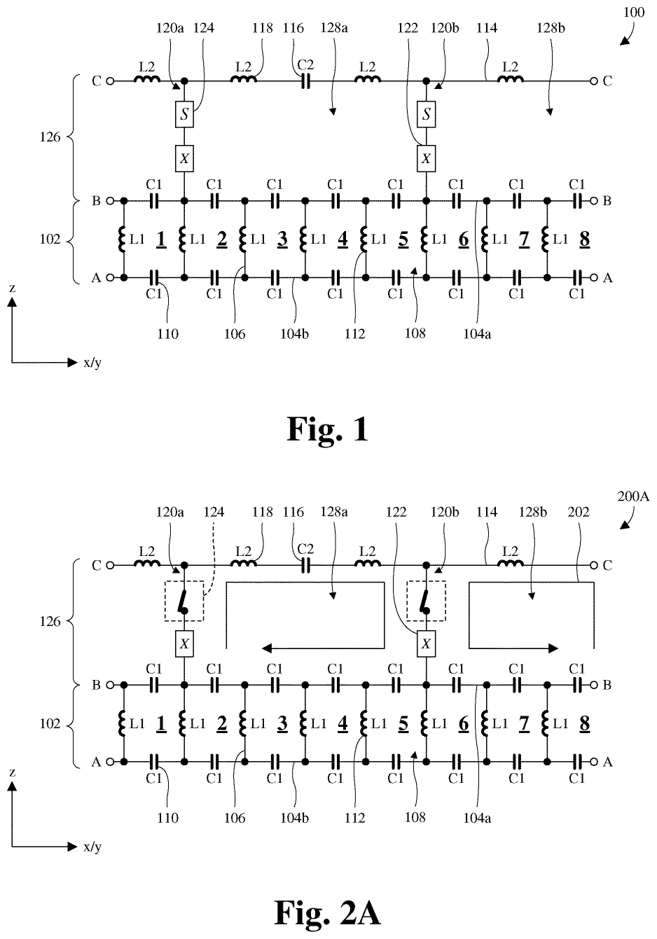

With reference to FIG. 1, a flattened view 100 of some embodiments of an MRI RF coil is provided in which the MRI RF coil comprises a birdcage coil 102 (e.g., a high-pass birdcage coil) employing RF shielding and end ring resonance for decoupling. Note that control circuitry, matching circuits, and other supporting electronics are not shown for simplicity.

The birdcage coil 102 comprises a first end ring 104a, a second end ring 104b, and a plurality of rungs 106. Opposite ends of the first end ring 104a, labeled A, are connected to each other, and opposite ends of the second end ring 104b, labeled B, are connected to each other. The plurality of rungs 106 extend from the first end ring 104a to the second end ring 104b and are spaced (e.g., evenly spaced) along the first and second end rings 104a, 104b.

The first end ring 104a, the second end ring 104b, and the plurality of rungs 106 are formed by conductive traces of copper or some other suitable material. Further, the first end ring 104a, the second end ring 104b, and the plurality of rungs 106 form a plurality of meshes 108. Each mesh is formed by a neighboring pair of rungs and segments of the first and second end rings 104a, 104b connecting the neighboring pair of rungs.

A plurality of birdcage capacitors 110 are on the first and second end rings 104a, 104b, and a plurality of birdcage inductors 112 are on the plurality of rungs 106, such that the birdcage coil 102 corresponds to a high-pass birdcage coil. In alternative embodiments, the birdcage coil 102 may correspond to a low-pass or band-pass birdcage coil.

The plurality of birdcage capacitors 110 share a capacitance value C1 and may, for example, correspond to discrete capacitors and/or breaks in conductive traces of the first and second end rings 104a, 104b. The plurality of birdcage inductors 112 share an inductance value L1 and may, for example, correspond to intrinsic inductance from conductive traces of the plurality of rungs 106. The capacitance value C1 and the inductance value L1 are selected so the birdcage coil 102 resonates at a working frequency. The working frequency may, for example, correspond to a Larmor frequency for hydrogen nuclei or the like.

The birdcage coil 102 corresponds to an 8-rung high-pass birdcage coil. Hence, the birdcage coil 102 has eight meshes, labeled 1 through 8. Further, the birdcage coil 102 has eight birdcage capacitors per end ring and one birdcage inductor per rung. In alternative embodiments, the birdcage coil 102 may have more or fewer rungs.

An RF shield 114 borders the first end ring 104a, with opposite ends of the RF shield 114, labeled C, connected to each other. The RF shield 114 is formed by conductive sheets of copper or another suitable material. Further, the RF shield 114 may, for example, be a shielding ring, a shielding tube, or an open birdcage shield. In some embodiments, the RF shield 114 is separated from the first end ring 104a by about 1-2 centimeters, about 1-1.5 centimeters, about 1.5-2 centimeters, or some other suitable value.

A direct current (DC) block capacitor 116 and a plurality of shield inductors 118 are spaced along the RF shield 114. The DC block capacitor 116, with a capacitance C2, corresponds to a discrete capacitor and/or a break in the conductive sheets of the RF shield 114. Further, the DC block capacitor 116 prevents the formation of a continuous conductive path that would otherwise generate eddy currents from a pulsed gradient coil during use of the MRI RF coil. In alternative embodiments, multiple DC block capacitors may be spaced along the RF shield 114 to further suppress eddy currents. The plurality of shield inductors 118 correspond to the intrinsic inductance of the conductive sheets forming the RF shield 114 and share an inductance value L2. Four shield inductors are illustrated, but more or fewer are amenable.

A first circuit branch 120a and a second circuit branch 120b are electrically coupled from the RF shield 114 to the first end ring 104a and are spaced, or about evenly spaced, along the first end ring 104a. For example, the first circuit branch 120a is electrically coupled to the first end ring 104a between meshes 1 and 2, and the second circuit branch 120b is electrically coupled to the first end ring 104a between meshes 5 and 6. Hence, the first and second circuit branches 120a, 120b are about 180 degrees apart from each other when the birdcage coil 102 is circumferentially arranged around an imaging volume.

A plurality of reactive branch components 122 and a plurality of switch components 124 are individual to and respectively on the first and second circuit branches 120a, 120b, such that each circuit branch comprises a switch component and a reactive branch component. Further, for a given circuit branch, the switch component and the reactive branch component are electrically coupled in series from the RF shield 114 to the first end ring 104a.

The plurality of reactive branch components 122 share a reactance value X and, more generally, share an impedance. The plurality of reactive branch components 122 may, for example, be or comprise branch inductors, branch capacitors, or combinations of branch capacitors and branch inductors electrically coupled in series and/or parallel. To the extent that the plurality of reactive branch components 122 comprise branch inductors, the branch inductors may, for example, correspond to solenoid inductors or the like.

In some embodiments, the plurality of reactive branch components 122 are branch inductors sharing an inductance value. In other embodiments, the plurality of reactive branch components 122 are branch capacitors sharing a capacitance value. In other embodiments, the plurality of reactive branch components 122 comprise a branch capacitor and a branch inductor electrically coupled in series and/or comprise a branch capacitor and a branch inductor electrically coupled in parallel. In other embodiments, the plurality of reactive branch components 122 share some other configuration of branch capacitors and/or branch inductors.

The plurality of switch components 124 have individual ON states and individual OFF states. In an ON state, a switch component has a low impedance and is effectively an electrical short. On the other hand, in an OFF state, a switch component has a high impedance and is effectively an open circuit. As seen hereafter, the plurality of switch components 124 may, for example, be electrically controlled and may, for example, be or comprise PIN diodes that are selectively biased to control switch states.

The first end ring 104a, the RF shield 114, the first circuit branch 120a, and the second circuit branch 120b collectively form a shield/end ring coil 126, which may also be known as a decoupling coil or the like. The shield/end ring coil 126 shares capacitors (e.g., birdcage capacitors) with the birdcage coil 102. Further, the shield/end ring coil 126 has a first resonant loop 128a and a second resonant loop 128b that are electrically coupled in parallel and work as one coil. One resonant loop corresponds to a B₁ field “point-in” side, and the other resonant loop corresponds to a B₁ field “point-out” side.

The first and second resonant loops 128a, 128b each comprise four birdcage capacitors (e.g., with capacitance value C1) and two shield inductors (e.g., with inductance value L2). In alternative embodiments, the first and second resonant loops 128a, 128b may have some other suitable number of birdcage capacitors and/or some other suitable number of shield inductors. Further, the first and second resonant loops 128a, 128b share the first and second circuit branches 120a, 120b, which comprise the branch inductors 1104.

The reactance value X of the plurality of reactive branch components 122 is selected so that, when the plurality of switch components 124 are in ON states, the plurality of reactive branch components 122 resonate with birdcage capacitors, shield inductors, and the DC block capacitor 116 at the working frequency of the birdcage coil 102. In other words, the reactance value X of the plurality of reactive branch components 122 is selected so that the first and second resonant loops 128a, 128b resonate at the working frequency. This so-called RF shielding and end ring resonance leads to a high impedance that blocks current and decouples the birdcage coil 102.

Note that the DC block capacitor 116 (e.g., C2) may also be used for tuning of resonance at the first resonant loop 128a. For example, the capacitance C2 of the DC block capacitor 116 may be selected, along with the reactance value X of the plurality of reactive branch components 122, to achieve resonance at the working frequency at the first resonant loop 128a. This increases the tuning flexibility. Further, in alternative embodiments, an additional DC block capacitor may be arranged along the RF shield 114, at the second resonant loop 128b, and may be used for tuning of the second resonant loop 128b.

Decoupling of the birdcage coil 102 entails preventing the birdcage coil 102 from generating or receiving any significant B₁ field. Since B₁ field components parallel to the B₀ field do not contribute to magnetic resonance (MR) signal generation, decoupling specifically targets the B₁ components orthogonal to the B₀ field. Assuming the B₀ field corresponds to the z-direction, this entails suppressing field components lying within the x-y plane.

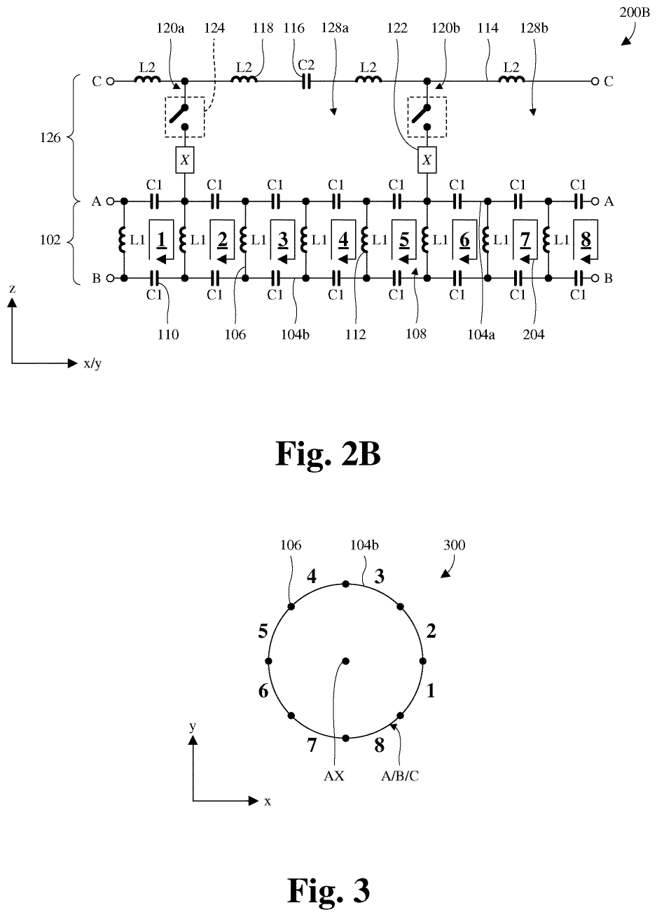

With reference to FIGS. 2A and 2B, flattened views 200A, 200B of some embodiments of the MRI RF coil of FIG. 1 are provided, in which the MRI RF coil is respectively in a birdcage-decoupled state and a birdcage-resonant state. When the MRI RF coil is used as a receive coil, the birdcage-decoupled state corresponds to Tx mode (when the coil is unused), and the birdcage-resonant state corresponds to Rx mode (when the coil is actively receiving). When the MRI RF coil is used as a transmit coil, the birdcage-decoupled state corresponds to Rx mode (when the coil is unused), and the birdcage-resonant state corresponds to Tx mode (when the coil is actively transmitting).

Focusing on FIG. 2A, which corresponds to the birdcage-decoupled state of the MRI RF coil, the switch components 124 are controlled so as to be in ON states (e.g., so as to have low impedances). This enables the RF shielding and end ring resonance at the working frequency. This resonance creates a high impedance along the first end ring 104a that blocks current in the birdcage coil 102 and blocks current from passing between the birdcage coil 102 and the shield/end ring coil 126, thereby decoupling the birdcage coil 102.

The RF shielding and end ring resonance is achieved via two parallel resonant paths: the first resonant loop 128a and the second resonant loop 128b. These two resonant paths are positioned on opposite sides of the imaging volume during MRI, about 180 degrees apart from each other, and have individual resonant currents 202 that flow through the first and second circuit branches 120a, 120b. The resonant currents 202 flow through the first circuit branch 120a in a first common direction and flow through the second circuit branch 120b in a second common direction opposite the first common direction. Because the RF shield 114 is close to the first end ring 104a and the plurality of reactive branch components 122 may be solenoid inductors, the B₁ field generated by the resonant currents 202 may be well contained, thereby minimizing unintended interaction with the scanned object.

Because the first and second resonant loops 128a, 128b are positioned about 180 degrees apart, the high impedance is localized primarily along a single direction (e.g., an x direction). As seen hereafter, full decoupling in both orthogonal directions (x and y) may be achieved using four resonant loops. However, decoupling in even a single direction is sufficient to disrupt the formation of the uniform mode in the birdcage coil 102. Whether operating in Tx or Rx mode, the uniform mode depends on current flow in both orthogonal directions. Thus, suppressing the current along the x direction effectively prevents the birdcage coil 102 from sustaining the uniform mode and generating or receiving any significant B₁ field, thereby achieving the objective of decoupling with a simplified circuit architecture.

Focusing on FIG. 2B, which corresponds to the birdcage-resonant state of the MRI RF coil, the switch components 124 are controlled so as to be in OFF states (e.g., so as to have high impedances). This disables the RF shielding and end ring resonance and disconnects the RF shield 114 from the first end ring 104a. Hence, the RF shield 114 acts as a stand-alone RF shield. Further, the birdcage coil 102 resonates at the working frequency, with currents 204 flowing in the plurality of meshes 108. This configuration allows the birdcage coil 102 to generate B₁ fields or receive MR signals, making it suitable for both TX mode and RX mode.

Compared to typical decoupling methods with PIN diodes on each birdcage rung and perhaps on each birdcage end ring, the total number of switch components (e.g., PIN diodes) may be greatly reduced (e.g., from ten to two). Further, because the plurality of switch components 124 are not part of the birdcage coil 102, switch-related loss (e.g., PIN diode-related loss) is reduced significantly (e.g., coil SNR increase). Therefore, the proposed RF shielding and end ring resonance for decoupling the birdcage coil 102 may significantly reduce the total number of PIN diodes and improve birdcage coil performance.

With reference to FIG. 3, an axial view 300 of some embodiments of the MRI RF coil of FIG. 1 is provided, in which the MRI RF coil extends circumferentially around an axis AX. Note that for the sake of simplicity, the MRI RF coil is shown from the second-end-ring side of the MRI RF coil and is further shown without birdcage capacitors. Hence, only the second end ring 104b and the plurality of rungs 106 are visible.

The axis AX may, for example, correspond to the z-direction (see, e.g., FIGS. 1, 2A, and 2B), such that the MRI RF coil extends circumferentially in the x and y directions. Further, as noted above, the z-direction may, for example, correspond to the B₀ field direction, whereas the x and y directions may correspond, for example, to the plane in which the B₁ field rotates. As illustrated and described with regard to FIGS. 1, 2A, and 2B, the x-direction is selectively decoupled by RF shielding and end ring resonance.

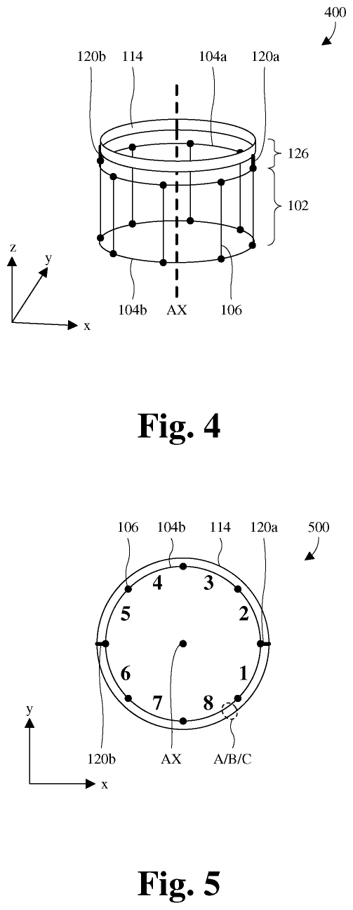

With reference to FIG. 4, a perspective view 400 of some embodiments of the MRI RF coil of FIG. 3 is provided in which the RF shield 114 corresponds to a shield ring proximate the first end ring 104a. As with FIG. 3, capacitors, inductors, and switches are not shown for the sake of simplicity. However, these components are as in FIGS. 1, 2A, and 2B.

The RF shield 114 has the same, or substantially the same, diameter as the birdcage coil 102. However, in alternative embodiments, the RF shield 114 may have a diameter that is greater than or less than the diameter of the birdcage coil 102.

With reference to FIG. 5, an axial view 500 of some alternative embodiments of the MRI RF coil of FIG. 1 is provided in which the RF shield 114 has a greater diameter than the birdcage coil 102. The axial view 500 may, for example, be as described for the axial view 300 of FIG. 3, except for the difference in diameter.

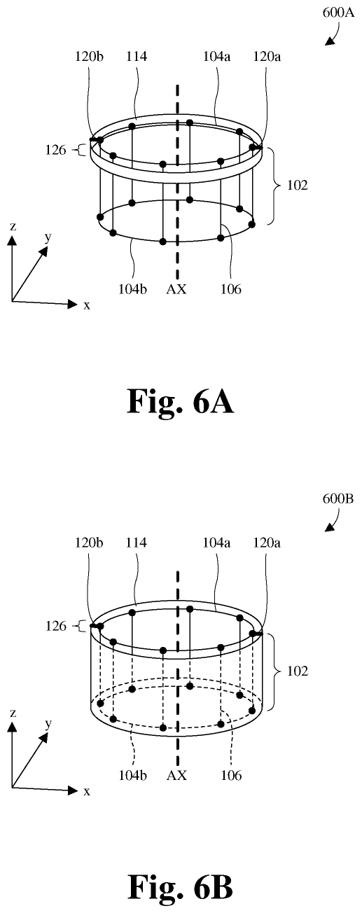

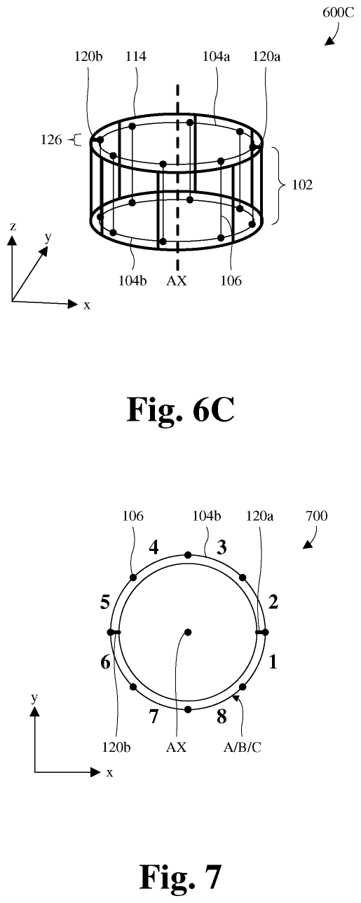

With reference to FIGS. 6A-6C, perspective views 600A-600C of some embodiments of the MRI RF coil of FIG. 5 are provided. In FIG. 6A, the RF shield 114 corresponds to a shield ring. In alternative embodiments of FIGS. 5 and 6A, the RF shield 114 may have a diameter that is less than the diameter of the birdcage coil 102. In FIG. 6B, the RF shield 114 corresponds to a shield tube surrounding the birdcage coil 102. In FIG. 6C, the RF shield 114 corresponds to a birdcage-like shield surrounding the birdcage coil 102.

With reference to FIG. 7, an axial view 700 of some alternative embodiments of the MRI RF coil of FIG. 1 is provided in which the RF shield 114 has a lesser diameter than the birdcage coil 102. The axial view 700 may, for example, be as described for the axial view 300 of FIG. 3, except for the difference in diameter.

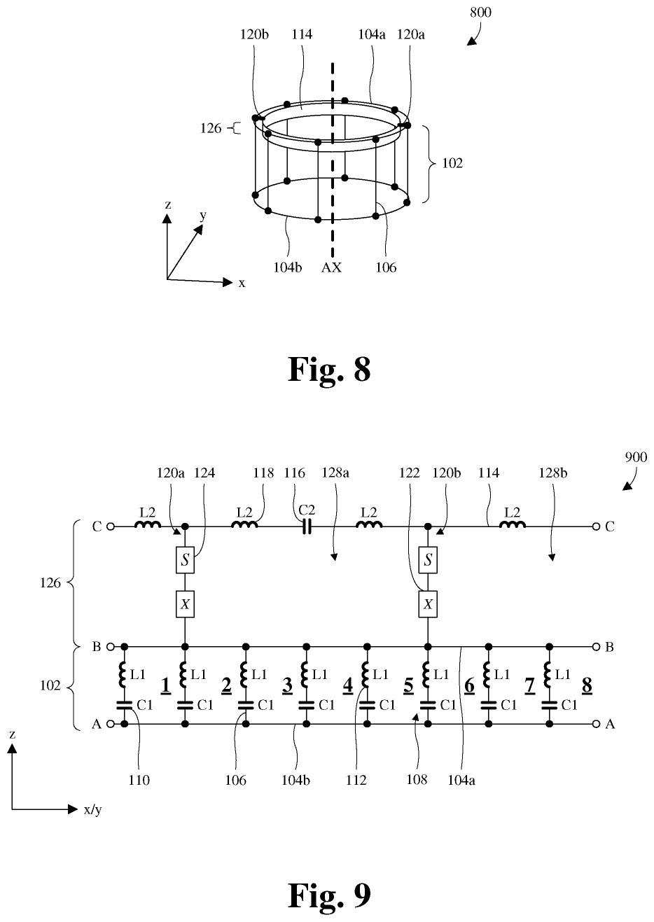

With reference to FIG. 8, a perspective view 800 of some embodiments of the MRI RF coil of FIG. 7 is provided in which the RF shield 114 corresponds to a shield ring.

With reference to FIG. 9, a flattened view 900 of some alternative embodiments of the MRI RF coil of FIG. 1 is provided in which the birdcage coil 102 is a low-pass birdcage coil. As such, the plurality of birdcage capacitors 110 are on the plurality of rungs 106 rather than on the first and second end rings 104a, 104b.

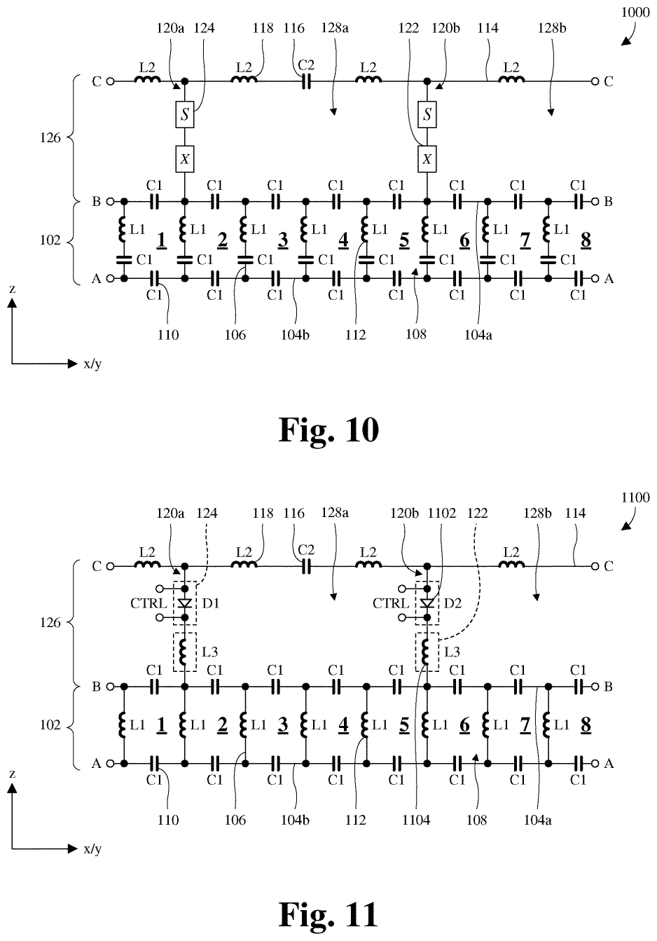

With reference to FIG. 10, a flattened view 1000 of some alternative embodiments of the MRI RF coil of FIG. 1 is provided in which the birdcage coil 102 is a band-pass birdcage coil. As such, the plurality of birdcage capacitors 110 are on both the first and second end rings 104a, 104b and the plurality of rungs 106.

With reference to FIG. 11, a flattened view 1100 of some embodiments of the MRI RF coil of FIG. 1 is provided in which the plurality of switch components 124 are or otherwise comprise individual PIN diodes 1102 and the plurality of reactive branch components 122 are or comprise individual branch inductors 1104. In alternative embodiments, and in place of the branch inductors 1104, the plurality of reactive branch components 122 may be or comprise individual capacitors, or individual combinations of branch capacitors and/or branch inductors that are electrically coupled in series and/or parallel.

The PIN diodes 1102, also labeled D1 and D2 respectively for the first and second circuit branches 120a, 120b, are configured to be selectively biased with a control signal CTRL to change between forward and reverse-biased states. In forward-biased states, the PIN diodes 1102 and hence the switch components 124 are in low impedance states. The low impedance states correspond to ON states that are effectively electrical shorts. In reverse-biased states, the PIN diodes 1102 and hence the switch components 124 are in high impedance states. The high impedance states correspond to OFF states that are effectively open circuits.

The branch inductors 1104 share an inductance value L3. The inductance value L3 is selected so that, when the plurality of switch components 124 are in ON states, the plurality of branch inductors 1104 resonate with birdcage capacitors (e.g., C1) and shield inductors (e.g., L2) at the working frequency of the birdcage coil 102. This may, for example, enable RF shielding and end ring resonance to decouple the birdcage coil 102.

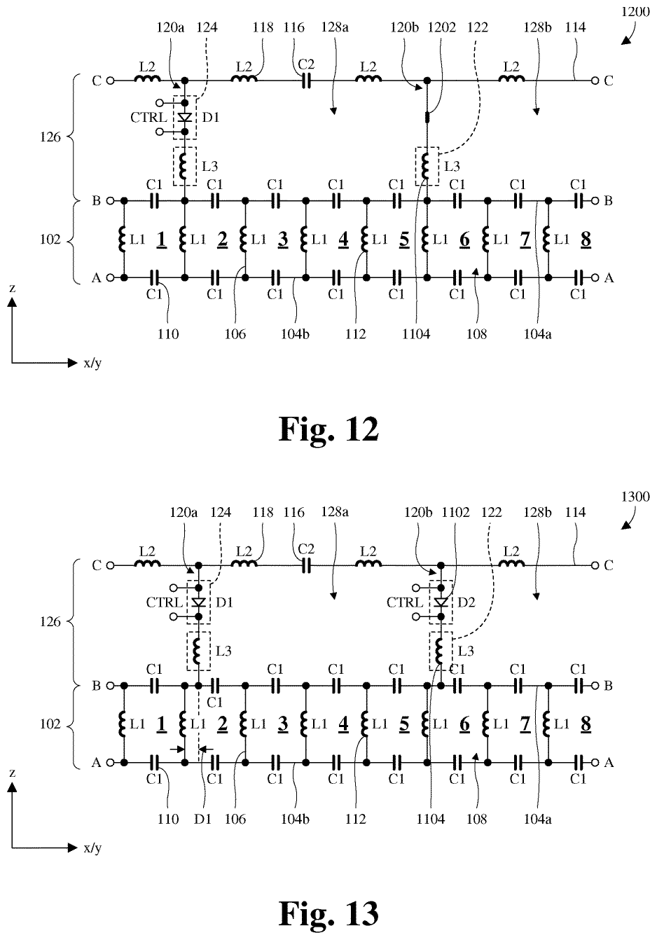

As seen above, two switch components (e.g., two PIN diodes) are employed for decoupling in the x direction. To reduce the number of switch components, the switch component 124 at the first or second circuit branch 120a, 120b may be replaced with an electrical short. For example, with reference to FIG. 12, a flattened view 1200 of some alternative embodiments of the MRI RF coil of FIG. 11 is provided in which the switch component 124 at the second circuit branch 120b is replaced with an electrical short 1202.

This does not affect how RF shielding and end ring resonance works (described above) because the plurality of switch components 124 are effectively electrical shorts during RF shielding and end ring resonance. Further, when RF shielding and end ring resonance is disabled (e.g., the switch component 124 of the first circuit branch 120a is OFF), the first circuit branch 120a is effectively electrically open and the RF shield 114 only connects to the birdcage coil 102 at one point (e.g., at the second circuit branch 120b). Hence, the RF shield 114 becomes a dangling conductor that is connected to the birdcage coil 102 at only one point. If the birdcage coil 102 is tuned to the working frequency properly with the RF shield 114 dangling off of it at that point, a single switch component (e.g., a single PIN diode) may be sufficient.

As seen above, the first and second circuit branches 120a, 120b have been aligned with rungs of the birdcage coil 102. However, the first and second circuit branches 120a, 120b may alternatively be offset from the plurality of rungs 106 so long as the first and second circuit branches 120a, 120b are separated by about 180 degrees. As an example, with reference to FIG. 13, a flattened view 1300 of some alternative embodiments of the MRI RF coil of FIG. 11 is provided in which the first and second circuit branches 120a, 120b are offset from neighboring rungs by a distance D1 and are separated by about 180 degrees. The distance D1 may, for example, correspond to about 10 degrees or some other suitable value.

As noted above, the objective of decoupling is to prevent the birdcage coil 102 from generating or receiving any significant B₁ field. Since B₁ field components parallel to the B₀ field do not contribute to MR signal generation, decoupling specifically targets the B₁ components orthogonal to the B₀ field. Assuming the B₀ field corresponds to the z-axis, this entails suppressing field components lying within the x-y plane.

Further, as noted above, the embodiments in the earlier figures include two resonant loops positioned about 180 degrees apart and configured to decouple in the x direction. For full decoupling in both orthogonal directions (e.g., x and y directions), two pairs of resonant loops may be employed. The resonant loops within each pair are about 180 degrees apart, and the resonant loops of each pair are about 90 degrees from the resonant loops of the other pair. The additional pair of resonant loops may be realized with additional circuit branches and, in some embodiments, an additional end ring that borders the second end ring 104b.

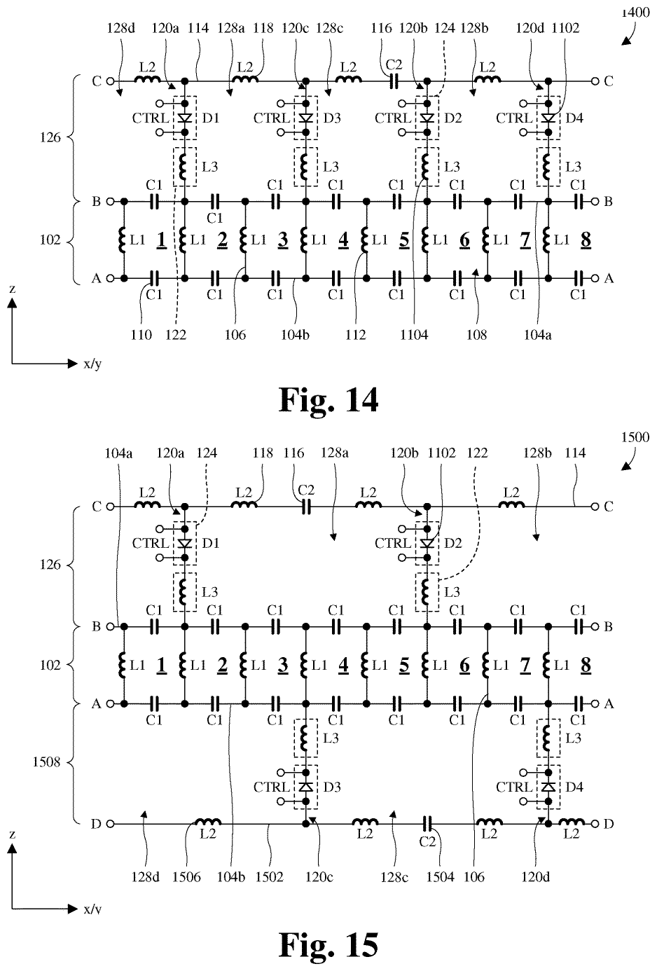

With reference to FIG. 14, a flattened view 1400 of some alternative embodiments of the MRI RF coil of FIG. 11 is shown with decoupling in multiple dimensions. The first and second circuit branches 120a, 120b are electrically coupled from the RF shield 114 to the first end ring 104a as in FIG. 11, and a third circuit branch 120c and a fourth circuit branch 120d are further electrically coupled from the RF shield 114 to the first end ring 104a.

The first, second, third, and fourth circuit branches 120a-120d are spaced from each other along the first end ring 104a with about 90 degrees separating each circuit branch from each neighboring circuit branch. Further, the third circuit branch 120c is between the first and second circuit branches 120a, 120b, and the first circuit branch 120a is between the third and fourth circuit branches 120c, 120d. Hence, the first and second circuit branches 120a, 120b are spaced apart from each other by about 180 degrees. Further, the third and fourth circuit branches 120c, 120d are spaced apart from each other by about 180 degrees and are about 90 degrees offset from the first and second circuit branches 120a, 120b.

In some embodiments, the first circuit branch 120a is electrically coupled to the first end ring 104a between meshes 1 and 2, and the second circuit branch 120b is electrically coupled to the first end ring 104a between meshes 5 and 6. Further, in some embodiments, the third circuit branch 120c is electrically coupled to the first end ring 104a between meshes 3 and 4, and the fourth circuit branch 120d is electrically coupled to the first end ring 104a between meshes 7 and 8. Other suitable connection points are, however, amenable.

Similar to earlier figures, the plurality of reactive branch components 122 and the plurality of switch components 124 are individual to and respectively on the first, second, third, and fourth circuit branches 120a-120d, such that each circuit branch comprises a switch component and a reactive branch component. Further, for a given circuit branch, the switch component and the reactive branch component of that circuit branch are electrically coupled in series from the RF shield 114 to the first end ring 104a.

The plurality of reactive branch components 122 are or otherwise comprise individual PIN diodes 1102, and the plurality of reactive branch components 122 are or comprise individual branch inductors 1104. In alternative embodiments, and in place of the branch inductors 1104, the plurality of reactive branch components 122 may be or comprise individual capacitors, or individual combinations of branch capacitors and/or branch inductors that are electrically coupled in series and/or parallel. The branch inductors 1104 share an inductance value L3, and hence the reactive branch components 122 share a reactance value.

The first end ring 104a, the RF shield 114, and the first, second, third, and fourth circuit branches 120a-120d collectively form the shield/end ring coil 126. The shield/end ring coil 126 has the first resonant loop 128a and the second resonant loop 128b that work together for x-direction decoupling. One resonant loop corresponds to a B₁ field “point-in” side, and the other resonant loop corresponds to a B₁ field “point-out” side. Further, the shield/end ring coil 126 has a third resonant loop 128c and a fourth resonant loop 128d that work together for y-direction decoupling. One resonant loop corresponds to a B₁ field “point-in” side, and the other resonant loop corresponds to a B₁ field “point-out” side.

The inductance value L3 of the branch inductors 1104 (and more generally the reactance value of the reactive branch components 122) is selected so that, when the plurality of switch components 124 are in ON states, the plurality of reactive branch components 122 resonate with birdcage capacitors and shield inductors at the working frequency of the birdcage coil 102. In other words, the inductance value L3 is selected so that the first, second, third, and fourth resonant loops 128a-128d resonate at the working frequency. This RF shielding and end ring resonance may decouple the birdcage coil 102.

In the birdcage-decoupled state of the MRI RF coil, the switch components 124 are controlled so as to be in ON states (e.g., so as to have low impedances). This enables the RF shielding and end ring resonance. This resonance creates a high impedance along the first end ring 104a that blocks current in the birdcage coil 102 and blocks current from passing between the birdcage coil 102 and the shield/end ring coil 126, thereby decoupling the birdcage coil 102. The RF shielding and end ring resonance is achieved via the resonant loops.

The first and second resonant loops 128a, 128b block current flow in the birdcage coil 102 in the x direction as described with regard to FIGS. 2A and 2B. Further, because the third and fourth resonant loops 128c, 128d are rotated 90 degrees relative to the first and second resonant loops 128a, 128b, the third and fourth resonant loops 128c, 128d block current flow in the birdcage coil 102 in the y direction in the same manner described for the x direction.

In the birdcage-resonant state of the MRI RF coil, the switch components 124 are controlled so as to be in OFF states (e.g., so as to have high impedances). This disables the RF shielding and end ring resonance and disconnects the RF shield 114 from the first end ring 104a. Hence, the RF shield 114 acts as a stand-alone RF shield. Further, the birdcage coil 102 resonates at the working frequency to generate B₁ fields or receive MR signals.

With reference to FIG. 15, a flattened view 1500 of some alternative embodiments of the MRI RF coil of FIG. 14 is provided in which the MRI RF coil comprises an additional RF shield 1502 bordering the second end ring 104b of the birdcage coil 102, on an opposite side of the birdcage coil 102 as the first end ring 104a of the birdcage coil 102. Further, the third and fourth circuit branches 120c, 120d are electrically coupled from the additional RF shield 1502 to the second end ring 104b, instead of from the RF shield 114 to the first end ring 104a. The RF shield 114 may also be referred to as the first RF shield 114, and the additional RF shield 1502 may also be referred to as the second RF shield 1502, or vice versa.

The additional RF shield 1502 is generally as described above for the RF shield 114 and has opposite ends, labeled D, that are connected to each other. Further, the additional RF shield 1502 is formed by conductive traces of copper or another suitable material. The additional RF shield 1502 may, for example, be a shielding ring or the like and may, for example, be separated from the second end ring 104b by about 1-2 centimeters, about 1-1.5 centimeters, about 1.5-2 centimeters, or some other suitable value.

An additional DC block capacitor 1504 and a plurality of additional shield inductors 1506 are spaced along the additional RF shield 1502. The additional DC block capacitor 1504, with a capacitance value C2, corresponds to a discrete capacitor and/or a break in the conductive traces of the additional RF shield 1502. Further, the additional DC block capacitor 1504 prevents the formation of a continuous conductive path that would otherwise generate eddy currents from a pulsed gradient coil during use of the MRI RF coil. In alternative embodiments, multiple DC block capacitors may be spaced along the additional RF shield 1502 to further suppress eddy currents. The plurality of additional shield inductors 1506 correspond to the intrinsic inductance of the conductive traces forming the additional RF shield 1502 and share an inductance value L2. Four shield inductors are illustrated, but more or fewer are amenable.

The first end ring 104a, the RF shield 114, the first circuit branch 120a, and the second circuit branch 120b collectively form the shield/end ring coil 126, which has the first and second resonant loops 128a, 128b. Further, the second end ring 104b, the additional RF shield 1502, the third circuit branch 120c, and the fourth circuit branch 120d collectively form an additional shield/end ring coil 1508, which has the third and fourth resonant loops 128c, 128d.

As above, the inductance value L3 of the branch inductors 1104 (and more generally the reactance value of the reactive branch components 122) is selected so that, when the plurality of switch components 124 are in ON states, the plurality of reactive branch components 122 resonate with birdcage capacitors and shield inductors at the working frequency of the birdcage coil 102. In other words, the inductance value L3 is selected so that the first, second, third, and fourth resonant loops 128a-128d resonate at the working frequency. This RF shielding and end ring resonance decouples the birdcage coil 102.

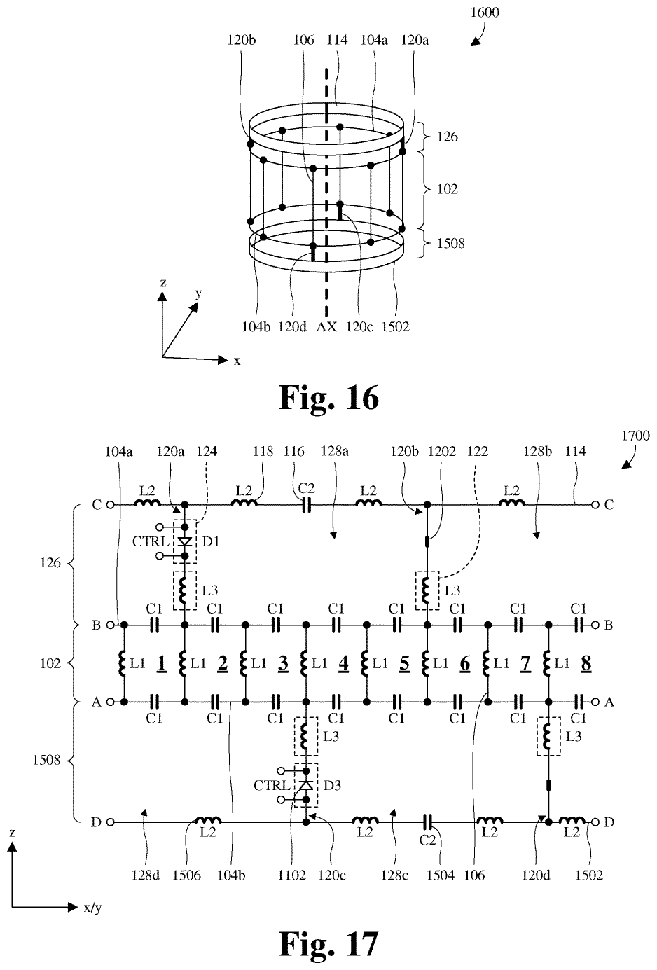

With reference to FIG. 16, a perspective view 1600 of some embodiments of the MRI RF coil of FIG. 15 is provided in which the RF shield 114 and the additional RF shield 1502 are shield rings respectively bordering the first and second end rings 104a, 104b of the birdcage coil 102. As with FIGS. 3 to 8, capacitors, inductors, and switches are not shown for the sake of simplicity. However, these components are as in FIG. 15.

The RF shield 114 and the additional RF shield 1502 have the same, or substantially the same, diameter as the birdcage coil 102. However, in alternative embodiments, the RF shield 114 and/or the additional RF shield 1502 may, for example, have a diameter that is greater than or less than a diameter of the birdcage coil 102.

With reference to FIG. 17, a flattened view 1700 of some alternative embodiments of the MRI RF coil of FIG. 15 is provided in which the switch components 124 at the second and fourth circuit branches 120b, 120d are replaced with electrical shorts 1202. This reduces the total number of switch components (e.g., PIN diodes) for full decoupling from four to two. As described above with regard to FIG. 12, the RF shielding and end ring resonance works the same when birdcage-decoupling the MRI RF coil. Further, when using the MRI RF coil in a birdcage resonance mode, the RF shield 114 and the additional RF shield 1502 dangle off the birdcage coil 102.

The present disclosure has thus far focused on x-direction and y-direction decoupling where each mesh 108 of the birdcage coil 102 shares only one end-ring capacitor (e.g., C1) with a single resonant loop (e.g., 128a, 128b) to decouple in one direction. In some cases, greater decoupling strength may be beneficial and can be achieved by sharing both birdcage capacitors in each mesh 108 with resonant loops in both directions.

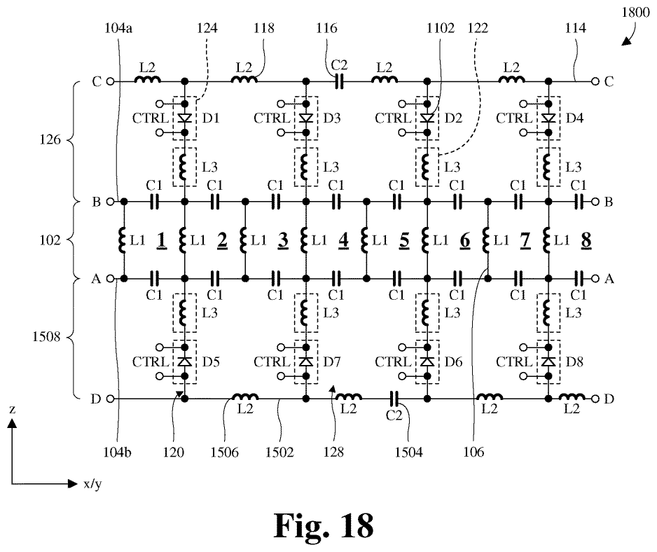

With reference to FIG. 18, a flattened view 1800 of some alternative embodiments of the MRI RF coil of FIG. 14 is provided in which the MRI RF coil comprises the additional RF shield 1502 and decouples in multiple directions (e.g., x and y) at each RF shield. A plurality of circuit branches 120 and a plurality of resonant loops 128 are split between the first end-ring side of the birdcage coil 102 and the second end-ring side of the birdcage coil 102.

Four circuit branches extend from the first end ring 104a to the RF shield 114 to form the shield/end ring coil 126, which comprises four resonant loops. Further, four circuit branches extend from the second end ring 104b to the additional RF shield 1502 to form the additional shield/end ring coil 1508, which comprises four resonant loops. The shield/end ring coil 126 may, for example, be as described with regard to FIG. 15, and the additional shield/end ring coil 1508 may, for example, be as the shield/end ring coil 126 is described with regard to FIG. 15, except for the use of the second end ring 104b instead of the first end ring 104a.

The plurality of circuit branches 120 and the plurality of resonant loops 128 are each as their counterparts are described in earlier figures. Hence, each circuit branch comprises a reactive branch component and a switch component electrically coupled in series from end ring to RF shield. Note that the switch components are labeled D1 to D8. Further, the four circuit branches of each shield/end ring coil are spaced from each neighbor by about 90 degrees circumferentially along corresponding end rings.

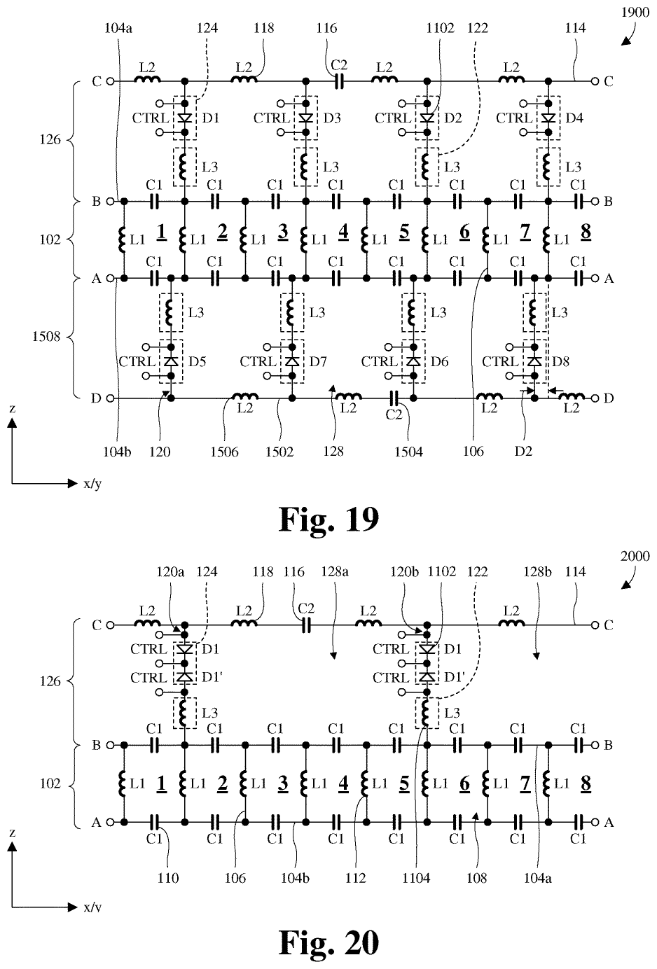

Note that the circuit branches 120 of the shield/end ring coil 126 are shown aligned with the circuit branches 120 of the additional shield/end ring coil 1508 and with rungs of the birdcage coil 102. However, so long as the circuit branches 120 within a shield/end ring coil (e.g., 126 or 1508) are separated by about 90 degrees, the circuit branches 120 of the shield/end ring coil 126 may be offset from the circuit branches 120 of the additional shield/end ring coil 1508 and/or laterally offset from rungs of the birdcage coil. FIG. 13 provides an example of the latter, whereas FIG. 19 provides an example of the former.

As seen with reference to FIG. 19, a flattened view 1900 of some alternative embodiments of the MRI RF coil of FIG. 18 is provided in which circuit branches 120 of the additional shield/end ring coil 1508 are laterally offset from circuit branches 120 of the RF shield 114 by a distance D2, which may, for example, correspond to about 10 degrees or some other suitable value. Hence, the shielding/end ring coil 126 and the additional shielding/end ring coil 1508 may have different definitions of the x and y directions.

If the MRI RF coil is used as a transmit coil (e.g., as a WBC or the like), the switch components 124 (e.g., PIN diodes) of the MRI RF coil may not be sufficient to block the high-power RF signal and to prevent resonance at the shield/end ring coil 126 and/or at the additional shield/end ring coil 1508. Hence, birdcage decoupling may unintentionally occur. Further, if the MRI RF coil is used as a local Tx/Rx birdcage coil and is left unplugged inside the MRI system due to human error, the MRI RF coil may again be exposed to a high-power RF signal that the switch components 124 are unable to block. This may lead to large induced RF currents in the MRI RF coil, which can cause excessive heating and pose a safety risk.

To address the challenges with high-power RF signals, several approaches may be used. One approach is for the plurality of switch components 124 to use anti-series PIN diodes with total withstanding voltages greater than the maximum voltage from the birdcage coil 102. For example, with reference to FIG. 20, a flattened view 2000 of some alternative embodiments of the MRI RF coil of FIG. 11 is provided in which each of the plurality of switch components 124 comprises a pair of PIN diodes 1102 in an anti-series configuration.

Further, when the MRI RF coil is used as a local Tx/Rx birdcage coil and is inadvertently left unplugged inside the MRI system, the anti-series configuration prevents the formation of resonant currents in the shield/end ring coil 126. This prevents excessive heating and mitigates the safety risks associated with unintended resonance.

The PIN diodes 1102 are configured as their counterparts are described above and are selectively biased with a control signal CTRL to change between forward and reverse-biased states. Further, the PIN diodes of the first circuit branch 120a are labeled D1 and D1′, and the PIN diodes of the second circuit branch 120b are labeled D2 and D2′.

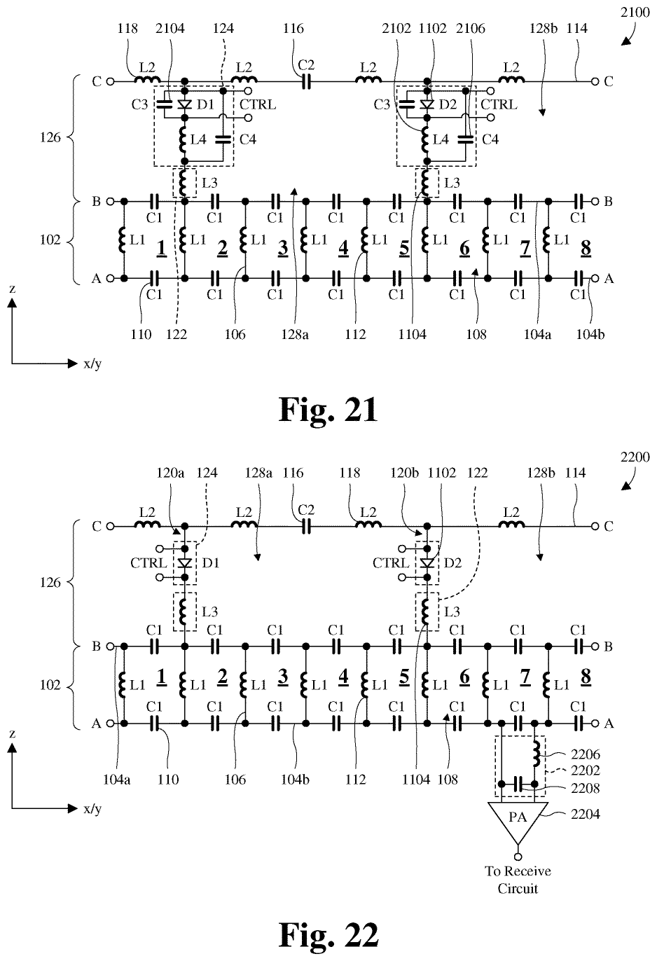

Another approach to address the problem of high-power RF signals is to convert the plurality of switch components 124 to resonant decoupling circuits so that the PIN diodes 1102 change from voltage-taking components to current-taking components with a PIN bias. Compared to PIN diodes alone for the switch components 124 (see, e.g., FIG. 11), the resonant decoupling circuit can handle higher power. As an example and with reference to FIG. 21, a flattened view 2100 of some alternative embodiments of the MRI RF coil of FIG. 11 is provided in which the plurality of switch components 124 are resonant decoupling circuits that operate similar to the RF shielding and end ring decoupling.

A plurality of PIN diodes 1102, a plurality of switch inductors 2102, a plurality of first switch capacitors 2104, and a plurality of second switch capacitors 2106 individually form the plurality of switch components 124, such that each switch component comprises a PIN diode, a switch inductor, a first switch capacitor, and a second switch capacitor. The plurality of PIN diodes 1102 are as above, the plurality of switch inductors 2102 share an inductance value L4, the plurality of first switch capacitors 2104 share a capacitance value C3, and the plurality of second switch capacitors 2106 share a capacitance value C4.

For a given switch component, the PIN diode, the switch inductor, and the first and second switch capacitors coordinate to create a resonant circuit. The PIN diode and the switch inductor are electrically coupled in series, and the first switch capacitor is electrically coupled in parallel with the PIN diode. Further, the second switch capacitor is electrically coupled in parallel with the series combination of the PIN diode and the switch inductor.

The inductance value L4 of the plurality of switch inductors 2102 and the capacitance value C3 of the plurality of first switch capacitors 2104 are selected so that the switch inductor and the first switch capacitor resonate in series at the working frequency (e.g., Larmor frequency) of the birdcage coil 102 when the PIN diode is in an OFF state. This effectively creates an electrical short across the first switch capacitor (e.g., C3) and the switch inductor (e.g., L4). The electrical short renders the second switch capacitor (e.g., C4) irrelevant because the second switch capacitor is in parallel with the electrical short. The OFF state corresponds to the high-impedance state of the PIN diode, in which the PIN diode is effectively an open circuit.

The inductance value L4 of the plurality of switch inductors 2102 and the capacitance value C4 of the plurality of second switch capacitors 2106 are selected so that the switch inductor and the second switch capacitor resonate in parallel at the working frequency of the birdcage coil 102 when the PIN diode is in an ON state. The ON state corresponds to the low-impedance state of the PIN diode, in which the PIN diode is effectively an electrical short. In some embodiments, the capacitance value C4 of the plurality of second switch capacitors 2106 is the same as the capacitance value C3 of the plurality of first switch capacitors 2104.

During use of the MRI RF coil, when the plurality of PIN diodes 1102 are in ON states, the MRI RF coil is in a birdcage resonant mode. The plurality of PIN diodes 1102 are effectively electrical shorts. Hence, the plurality of first switch capacitors 2104 (e.g., being electrically coupled in parallel with these electrical shorts) may be ignored. Further, the plurality of switch inductors 2102 resonate in parallel with the plurality of second switch capacitors 2106 to create high impedances (e.g., effective open circuits), separating the plurality of branch inductors 1104 from the RF shield 114. As a result, the birdcage coil 102 may resonate as normal with the RF shield 114 being disconnected from the birdcage coil 102.

When the plurality of PIN diodes 1102 are in OFF states, the MRI RF coil is in a birdcage decoupled mode. The plurality of PIN diodes 1102 are effectively open circuits. Hence, the plurality of first switch capacitors 2104 and the plurality of switch inductors 2102 resonate in series to create a low impedance (e.g., an effective electrical short). Because of the electrical short, the plurality of second switch capacitors 2106 (e.g., being electrically coupled in parallel with these electrical shorts) may be ignored. Further, because of the electrical short, the plurality of branch inductors 1104 are electrically coupled to the RF shield 114, and the RF shielding and end ring resonance may decouple the birdcage coil 102.

Note that compared to previous embodiments, the embodiments of FIG. 21 change the PIN diode control logic for switching the birdcage coil 102 between the resonant mode and the non-resonant mode (e.g., disabled mode). For example, for the embodiments of FIG. 21, the plurality of PIN diodes 1102 being ON means the birdcage coil 102 resonates, and the plurality of PIN diodes 1102 being OFF means the birdcage coil 102 is non-resonant. In contrast, for previous embodiments (e.g., the embodiments in any one or combination of FIGS. 1 to 20), the plurality of PIN diodes 1102 being OFF means the birdcage coil 102 resonates, and the plurality of PIN diodes 1102 being ON means the birdcage coil 102 is non-resonant.

As seen above, a switch component may be or otherwise comprise a single PIN diode (see, e.g., FIG. 11), a pair of anti-series PIN diodes (see, e.g., FIG. 21), or a resonant decoupling circuit (see, e.g., FIG. 21). However, there are practically many other circuits that achieve this switching function, as long as the circuit can switch between the high-impedance, high-power state (or unplugged state) and the low-impedance state with PIN bias control.

Further, an additional benefit from using resonant decoupling circuits for the plurality of switch components 124, as described with regard to FIG. 21, is that the plurality of second switch capacitors 2106 may also be used to tune the birdcage coil 102.

When the PIN diodes 1102 are in ON states and the MRI RF coil is in a birdcage resonant mode, the plurality of switch inductors 2102 resonate in parallel with the plurality of second switch capacitors 2106 to create high impedances. As described above, this resonance is generally at the working frequency (e.g., the Larmor frequency) of the birdcage coil 102. However, if the capacitance value C4 of the plurality of second switch capacitors 2106 is changed so that it deviates from the value at the working frequency, there may be more or less capacitance between the RF shield 114 and the first end ring 104a.

If the impedance from this more or less capacitance is large compared to the impedance of the plurality of branch inductors 1104, then this more or less capacitance is dominant and can be used to tune the birdcage coil 102. The reason is that the RF shield 114 helps to put the more or less capacitance on all birdcage capacitors around the first end ring 104a instead of on one birdcage capacitor. This benefit makes the birdcage tuning more effective because the traditional method is to tune many capacitors in the birdcage coil 102.

With reference to FIG. 22, a flattened view 2200 of some embodiments of the MRI RF coil of FIG. 11 is provided in which the MRI RF coil comprises a matching circuit 2202 and a preamplifier 2204. The matching circuit 2202 is electrically coupled across one of the birdcage capacitors 110 and comprises at least one matching inductor 2206 and at least one matching capacitor 2208 configured to match an impedance of the birdcage coil 102 to an expected impedance at an input of the preamplifier 2204. This expected impedance may, for example, correspond to 50 ohms or some other suitable value. An output of the preamplifier 2204 electrically couples to a receive circuit or the like of an MRI system.

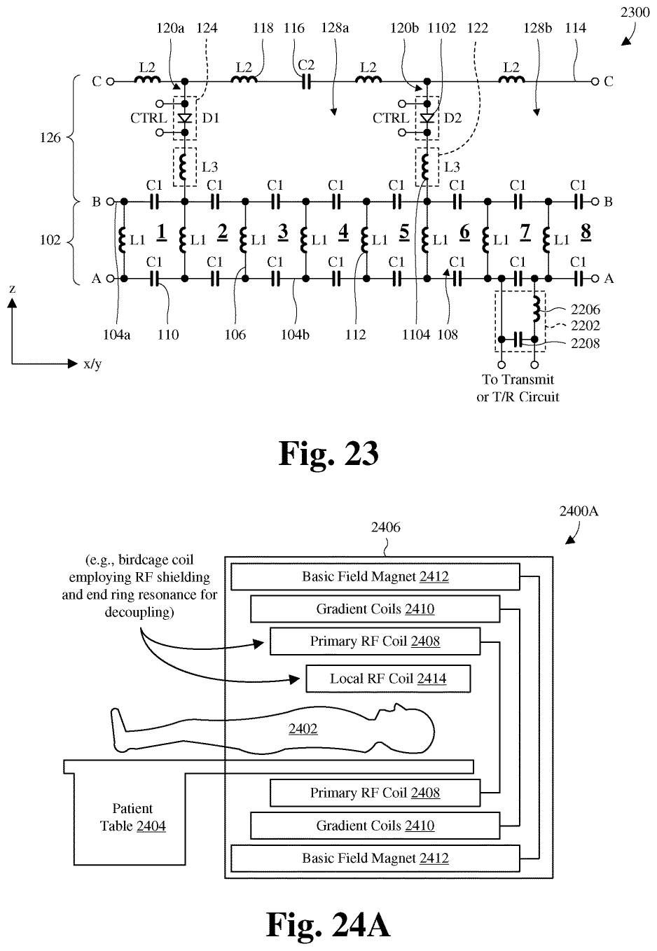

With reference to FIG. 23, a flattened view 2300 of some alternative embodiments of the MRI RF coil of FIG. 22 is provided in which the preamplifier 2204 is omitted. In such embodiments, an input/output (I/O) port of the match circuit 2202 may be electrically coupled to a transmit/receive (T/R) switch of an MRI system or a transmit circuit of the MRI system.

While FIGS. 11 to 23 illustrate the plurality of reactive branch components 122 as being or comprising branch inductors 1104, the plurality of reactive branch components 122 may be or comprise individual branch capacitors, or individual combinations of branch capacitors and/or branch inductors that are electrically coupled in series and/or parallel, in alternative embodiments. While FIGS. 12 to 19, 22, and 23 illustrate the plurality of switch components 124 as being or comprising the PIN diodes 1102, the plurality of switch components 124 may alternatively be or comprise pairs of anti-series PIN diodes (see, e.g., FIG. 20) or resonant switch components (see, e.g., FIG. 21). While FIGS. 22 and 23 illustrate the MRI RF coil of FIG. 11 with the matching circuit 2202 and the preamplifier 2204, it is to be appreciated that variants of the MRI RF coils in FIGS. 12 to 21 may further include the matching circuit 2202 and the preamplifier 2204 (see, e.g., FIG. 22) or may further include the matching circuit 2202 alone (see, e.g., FIG. 23). While FIGS. 11 to 23 illustrate the birdcage coil 102 as a high-pass birdcage coil, the birdcage coil 102 may alternatively be a low-pass or band-pass birdcage coil.

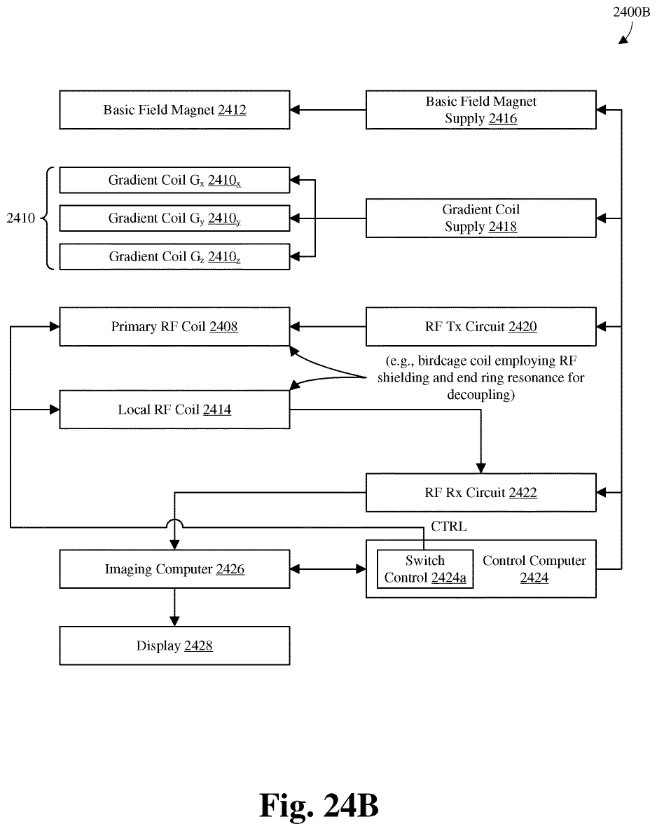

With reference to FIGS. 24A and 24B, various diagrams 2400A, 2400B of some embodiments of an MRI system comprising an MRI RF coil with RF shielding and end ring resonance for decoupling are provided. FIG. 24A illustrates a high-level diagram 2400A of the MRI system, whereas FIG. 24B illustrates a block diagram 2400B of the MRI system.

Focusing on FIG. 24A, a patient 2402 is arranged on a patient table 2404, which is configured to move the patient 2402 into and out of a bore of a scanner 2406. Within the scanner 2406, the MRI system comprises a primary RF coil 2408, gradient coils 2410, and a basic field magnet 2412. The basic field magnet 2412 generates a magnetic field, and the primary RF coil 2408 transmits RF pulses to and/or receives MR signals from tissue of the patient 2402. The received MR signals are used to create diagnostic images of the tissue. A shield may substantially contain the magnetic fields, RF pulses, and MR signals within the scanner 2406.

In some embodiments, the primary RF coil 2408 is a WBC configured to operate, in conjunction with the gradient coils 2410, primarily as a transmission device to transmit RF pulses to the patient 2402. The WBC is intended for imaging large portions of the patient 2402. However, the WBC may alternatively be used as a receive device, or as both a transmit and receive device. In lieu of or in addition to the WBC, a local RF coil 2414 (e.g., a surface coil or phased array coil) may be employed to transmit RF pulses to and/or receive MR signals from the patient 2402, offering improved SNR for imaging localized regions of interest. The primary RF coil 2408 and/or the local RF coil 2414 may, for example, correspond to the MRI RF coil in any one or combination of FIGS. 1 to 23.

Focusing on FIG. 24B, the basic field magnet 2412 is electrically coupled to a basic field magnet supply 2416 and is configured to generate a static B₀ magnetic field. Ideally, the B₀ field is uniform or substantially uniform across the imaging volume. However, in practice, the B₀ field may vary across the object being imaged.

The gradient coils 2410 are electrically coupled to and controlled, at least in part, by a gradient coil supply 2418. The gradient coils 2410 are configured to emit gradient magnetic fields, specifically Gₓ, G_{y}, and G_{z}, via associated gradient coils 2410ₓ, 2410_{y}, and 2410_{z}, respectively. The timing, strength, and orientation of the gradient magnetic fields may be selectively controlled and adapted during an MRI procedure to spatially encode the MR signals.

The primary RF coil 2408 is electrically coupled to an RF transmission circuit 2420 and is configured to transmit RF pulses to the patient 2402. In alternative embodiments, the primary RF coil 2408 is further configured to receive MR signals from the patient 2402 and is further electrically coupled to an RF receive circuit 2422. Accordingly, the primary RF coil 2408 may operate as a Tx coil or, in some embodiments, as a Tx/Rx coil. As used herein, an RF coil configured solely to transmit RF pulses may be referred to as a Tx coil, an RF coil configured solely to receive MR signals may be referred to as an Rx coil, and an RF coil configured to both transmit RF pulses and receive MR signals may be referred to as a Tx/Rx coil.

As noted above, in lieu of or in addition to the primary RF coil 2408, the local RF coil 2414 may be employed to transmit RF pulses to and/or receive MR signals from the patient 2402. The local RF coil 2414 is smaller than the primary RF coil 2408 and may, for example, be positioned on or near the patient 2402 within the bore of the scanner 2406. Being in closer proximity to the patient 2402, the local RF coil 2414 may provide improved SNR compared to the primary RF coil 2408 for imaging localized regions of interest.

The local RF coil 2414 may be configured as an Rx coil, a Tx coil, or a Tx/Rx coil. When configured as an Rx coil, the local RF coil 2414 is electrically coupled to the RF receive circuit 2422. The RF receive circuit 2422 may, for example, include a dedicated receiver electrically coupled to each channel of the local RF coil 2414. When configured as a Tx coil, the local RF coil 2414 is electrically coupled to the RF transmission circuit 2420. The RF transmission circuit 2420 may, for example, include a dedicated transmitter electrically coupled to each channel of the local RF coil 2414.

As noted above, the primary RF coil 2408 and/or the local RF coil 2414 may, for example, correspond to the MRI RF coil in any one or combination of FIGS. 1 to 23. A control computer 2424 may include a switch control circuit 2424a configured to generate a CTRL signal for the one or more switch components 124 to selectively enable RF shielding and end ring resonance to decouple the MRI RF coil as described above.

To the extent that the one or more switch components 124 are or otherwise comprise PIN diodes, the switch control circuit 2424a may also be regarded as PIN control circuitry, PIN bias circuitry, or the like. The switch control circuit 2424a may bias the PIN diodes to change the PIN diodes between ON states and OFF states. For embodiments of the MRI RF coil in any one or combination of FIGS. 1-20, 22, and 23, the ON states disable resonance of the birdcage coil, whereas the OFF states enable such resonance. For embodiments of the MRI RF coil in FIG. 21, the PIN diode control logic is the opposite. The ON states enable resonance of the birdcage coil, whereas the OFF states disable such resonance.

In embodiments in which the MRI RF coil in any one or combination of FIGS. 1 to 23 is used as an Rx coil (e.g., the local RF coil 2414 is the MRI RF coil), the MRI RF coil may have the matching circuit 2202 and the preamplifier 2204 as in FIG. 22. An output of the preamplifier 2204 may be electrically coupled to the RF receive circuit 2422. Further, the switch control circuit 2424a may control the one or more switch components of the MRI RF coil to enable RF shielding and end ring resonance during Tx mode to birdcage-decouple the MRI RF coil.

In embodiments in which the MRI RF coil in any one or combination of FIGS. 1 to 23 is used as a Tx coil (e.g., the primary RF coil 2408 is the MRI RF coil), the MRI RF coil may have the matching circuit 2202 as in FIG. 23. An I/O port of the matching circuit 2202 may be electrically coupled to the RF transmission circuit 2420. Further, the switch control circuit 2424a may control the one or more switch components of the MRI RF coil to enable RF shielding and end ring resonance during Rx mode to birdcage-decouple the MRI RF coil.

The gradient coil supply 2418 and the RF transmission circuit 2420 are controlled, at least in part, by a control computer 2424. MR signals received by the local RF coil 2414 are passed to the RF receive circuit 2422, and the resulting data may subsequently be employed to generate a diagnostic image of the patient 2402. The diagnostic image is generated via a transformation process, such as a two-dimensional (2D) fast Fourier transform (FFT), producing image data that may be processed by an image computer 2426 and displayed on a display 2428 for review. The RF receive circuit 2422 may, for example, be electrically coupled to the control computer 2424 and/or to the image computer 2426.

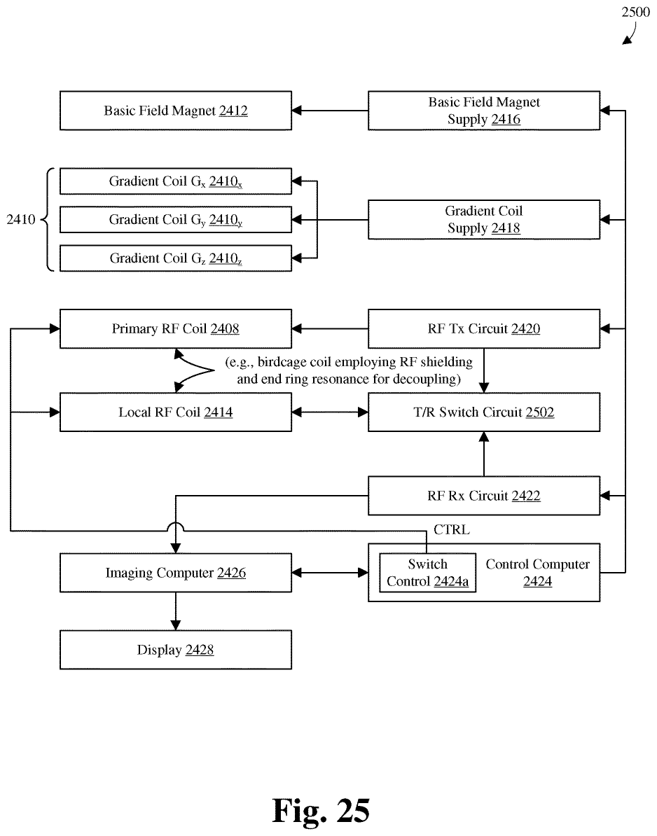

With reference to FIG. 25, a diagram 2500 of some alternative embodiments of the MRI system according to FIGS. 24A and 24B is provided in which the MRI system further comprises a T/R switch circuit 2502.

The T/R switch circuit 2502 is configured to electrically couple the local RF coil 2414 selectively to the RF transmission circuit 2420 and the RF receive circuit 2422. For example, in Rx mode, the T/R switching circuit 2502 may be controlled to electrically couple the local RF coil 2414 to the RF receive circuit 2422. Further, in Tx mode, the T/R switching circuit 2502 may be controlled to electrically couple the local RF coil 2414 to the RF transmission circuit 2420. Such control may, for example, be by the control computer 2424 or by some other suitable device. In alternative embodiments, the primary RF coil 2408 may be electrically coupled to the T/R switch circuit 2502 in place of the local RF coil 2414, or the primary RF coil 2408 may be otherwise electrically coupled to another T/R switch circuit 2502.

In embodiments in which the MRI RF coil in any one or combination of FIGS. 1 to 23 is used as a Tx/Rx coil (e.g., the primary RF coil 2408 or the local RF coil 2414 is the MRI RF coil), the MRI RF coil may have the matching circuit 2202 as in FIG. 23. An I/O port of the matching circuit 2202 may be electrically coupled to the T/R switch circuit 2502. Further, the switch control circuit 2424a may control the one or more switch components of the MRI RF coil to enable RF shielding and end ring resonance when the MRI RF coil is unused.

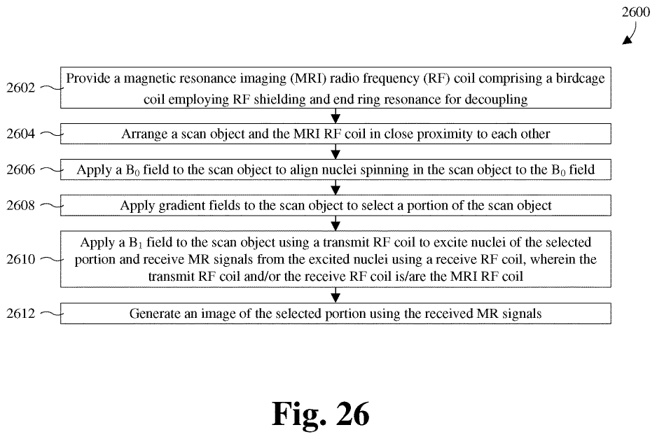

With reference to FIG. 26, a block diagram 2600 of some embodiments of a method for performing MRI using an MRI RF coil according to aspects of the present disclosure is provided. The method may, for example, be employed using the MRI system in FIGS. 24A and 24B, the MRI system in FIG. 25, or some other suitable MRI system.

At act 2602, an MRI RF coil comprising a birdcage coil employing RF shielding and end ring resonance for decoupling is provided. The MRI RF coil may, for example, correspond to the MRI RF coil in any one or combination of FIGS. 1 to 23.

At act 2604, a scan object (e.g., a patient) and the MRI RF coil are arranged in close proximity to each other.

At act 2606, a B₀ field is applied to the scan object to align nuclei spinning in the scan object to the B₀ field.

At act 2608, gradient fields are applied to the scan object to select a portion of the scan object.

At act 2610, a B₁ field is applied to the scan object using a transmit RF coil to excite nuclei of the selected portion. Further, MR signals are received from the excited nuclei using a receive RF coil. The transmit RF coil and/or the receive RF coil is/are the MRI RF coil.

At act 2612, an image of the selected portion is generated using the received MR signals.

Collectively, acts 2604 to 2612 may be regarded as the act of performing MRI on the scan object to generate the image of the scan object using the MRI RF coil as the transmit RF coil and/or as the receive RF coil.

While the block diagram 2600 of FIG. 26 is illustrated and described herein as a series of acts or events, it will be appreciated that the illustrated ordering of such acts or events is not to be interpreted in a limiting sense. For example, some acts may occur in different orders and/or concurrently with other acts or events apart from those illustrated and/or described herein. Further, not all illustrated acts may be required to implement one or more aspects or embodiments of the description herein, and one or more of the acts depicted herein may be carried out in one or more separate acts and/or phases.

In view of the foregoing, some embodiments of the present disclosure are directed to an MRI RF coil, including: a birdcage coil including a first end ring, a second end ring, and a plurality of rungs extending from the first end ring to the second end ring; a first RF shield bordering the first end ring; a first circuit branch electrically coupled from the first RF shield to the first end ring and including a first switch component; and a second circuit branch electrically coupled from the first RF shield to the first end ring; wherein the first end ring, the first RF shield, the first circuit branch, and the second circuit branch form a first resonant decoupling coil configured to selectively resonate at a working frequency of the birdcage coil. In some embodiments, the first resonant decoupling coil is configured to resonate at the working frequency of the birdcage coil to create a high impedance path along the first end ring and to decouple the birdcage coil in response to the first switch component being in an ON state. In some embodiments, the second circuit branch includes a second switch component, wherein the first resonant decoupling coil is configured to resonate at the working frequency of the birdcage coil to decouple the birdcage coil in response to both the first and second switch components being in ON states. In some embodiments, the second circuit branch is devoid of a switch component. In some embodiments, the MRI RF coil further includes a third circuit branch and a fourth circuit branch electrically coupled from the first RF shield to the first end ring, wherein the first, second, third, and fourth circuit branches are circumferentially spaced around the first end ring with about 90 degrees separating each circuit branch from each neighboring circuit branch. In some embodiments, the MRI RF coil further includes: a second RF shield bordering the second end ring; and a plurality of additional circuit branches electrically coupled from the second RF shield to the second end ring, wherein the second end ring, the second RF shield, and the plurality of additional circuit branches form a second resonant decoupling coil configured to selectively resonate at the working frequency of the birdcage coil. In some embodiments, the first switch component consists essentially of a diode. In some embodiments, the first switch component includes a pair of anti-series diodes. In some embodiments, the first switch component includes: a series inductor-capacitor (LC) resonant circuit; a parallel LC resonant circuit sharing a reactive element with the series LC resonant circuit; and a diode configured to selectively toggle between a first state in which the series LC resonant circuit resonates to create a low impedance activating the decoupling coil, and a second state in which the parallel LC resonant circuit resonates to create a high impedance deactivating the decoupling coil. In some embodiments, the first switch component is configured for global tuning of the birdcage coil while the birdcage coil is in a resonant mode. In some embodiments, the first RF shield corresponds to a ring-shaped structure bordering the first end ring. In some embodiments, the first RF shield corresponds to a conductive tube surrounding the birdcage coil. In some embodiments, the first RF shield corresponds to a birdcage structure surrounding the birdcage coil.

Further, other embodiments of the present disclosure provide an MRI system, including: an MRI RF coil, including: a birdcage coil including a first end ring, a second end ring, and a plurality of rungs extending from the first end ring to the second end ring; and a decoupling coil sharing the first end ring with the birdcage coil and including: a first RF shield; and a plurality of circuit branches electrically coupled from the first RF shield to the first end ring and including a first circuit branch, which includes a first switch component; an RF circuit electrically coupled to the birdcage coil; and a control computer electrically coupled to the first switch component and configured to control the first switch component to change the decoupling coil between a resonant mode and a non-resonant mode, wherein the resonant mode decouples the birdcage coil. In some embodiments, the decoupling coil has a total of one switch component and a total of two circuit branches electrically coupled from the first end ring to the first RF shield. In some embodiments, the decoupling coil has a total of two switch components and a total of two or four circuit branches electrically coupled from the first end ring to the first RF shield. In some embodiments, the decoupling coil has a total of four switch components and a total of four circuit branches electrically coupled from the first end ring to the first RF shield. In some embodiments, the decoupling coil is configured to decouple the birdcage coil from multiple directions that are orthogonal to each other and to an axis of the birdcage coil around which the first and second end rings extend circumferentially. In some embodiments, the first switch component has a first state that decouples the birdcage coil while the first switch component is electrically controlled, a second state that enables resonance of the birdcage coil while the first switch component is electrically controlled, and a third state that decouples the birdcage coil while the first switch component is electrically disconnected.

Further, other embodiments of the present disclosure provide a method, including: providing an RF coil that includes a birdcage coil, a first RF shield bordering a first end ring of the birdcage coil, and a plurality of circuit branches electrically coupled from the first end ring to the first RF shield, wherein a first circuit branch of the plurality of circuit branches includes a first switch component, and wherein the plurality of circuit branches, the first end ring, and the first RF shield form a decoupling coil; performing MRI on a scan object to generate an image of the scan object using the birdcage coil as a transmit coil and/or a receive coil; and controlling the first switch component while performing the MRI to change the decoupling coil between a resonant mode and a non-resonant mode, wherein the resonant mode resonates at the same resonant frequency as the birdcage coil and decouples the birdcage coil.

The following includes definitions of selected terms employed herein. The definitions include various examples or forms of components that fall within the scope of a term and that may be used for implementation. The examples are not intended to be limiting. Both singular and plural forms of terms may be within the definitions.

The terminology used herein is for the purpose of describing particular embodiments only and is not intended to be limiting of example embodiments. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which embodiments belong. It will be further understood that terms (e.g., those defined in commonly used dictionaries) should be interpreted as having a meaning that is consistent with their meaning in the context of the relevant art and will not be interpreted in an idealized or overly formal sense unless expressly so defined herein.

In the above description, some components may be displayed in multiple figures carrying the same reference signs and/or names but are not necessarily described multiple times in detail. A detailed description of a component may then apply to that component for all its occurrences. Further, numerical designations (e.g., first, second, third, etc.) may be used for clarity to distinguish between components of the same type. However, it is to be appreciated that the numerical designation may vary for components displayed in multiple figures, depending upon context. For example, a component referred to as third in one figure may be referred to as fourth in another figure if another component of the same type already has the designation of third.

The detailed descriptions presented herein may be presented in terms of algorithms and symbolic representations of operations on data bits within a memory. These algorithmic descriptions and representations are used by those skilled in the art to convey the substance of their work to others. An algorithm, here and generally, is conceived to be a sequence of operations that produce a result. The operations may include physical manipulations of physical quantities. Usually, though not necessarily, the physical quantities take the form of electrical or magnetic signals capable of being stored, transferred, combined, compared, or otherwise manipulated by logic, and so on. The physical manipulations create a concrete, tangible, useful, real-world result.

It has proven convenient at times, principally for reasons of common usage, to refer to these signals as bits, values, elements, symbols, characters, terms, numbers, and so on. It should be borne in mind, however, that these and similar terms are to be associated with the appropriate physical quantities and are merely convenient labels applied to these quantities. Unless specifically stated otherwise, it is appreciated that throughout the description, terms including processing, computing, calculating, determining, and so on refer to actions and processes of a computer system, logic, processor, or similar electronic device that manipulates and transforms data represented as physical and/or electronic quantities.

Example methods may be better appreciated with reference to flow diagrams. While for purposes of simplicity of explanation, the illustrated methodologies are shown and described as a series of blocks, it is to be appreciated that the methodologies are not limited by the order of the blocks, as some blocks can occur in different orders and/or concurrently with other blocks from that shown and described. Moreover, less than all the illustrated blocks may be required to implement an example methodology. Blocks may be combined or separated into multiple components. Furthermore, additional and/or alternative methodologies can employ additional, not illustrated blocks.

What is claimed is:

1. A magnetic resonance imaging (MRI) radio frequency (RF) coil, comprising:
a birdcage coil comprising a first end ring, a second end ring, and a plurality of rungs extending from the first end ring to the second end ring;
a first RF shield bordering the first end ring;
a first circuit branch electrically coupled from the first RF shield to the first end ring and comprising a first switch component; and
a second circuit branch electrically coupled from the first RF shield to the first end ring;
wherein the first end ring, the first RF shield, the first circuit branch, and the second circuit branch form a first resonant decoupling coil configured to selectively resonate at a working frequency of the birdcage coil.

2. The MRI RF coil according to claim 1, wherein the first resonant decoupling coil is configured to resonate at the working frequency of the birdcage coil to create a high impedance path along the first end ring and to decouple the birdcage coil in response to the first switch component being in an ON state.

3. The MRI RF coil according to claim 1, wherein the second circuit branch comprises a second switch component, and wherein the first resonant decoupling coil is configured to resonate at the working frequency of the birdcage coil to decouple the birdcage coil in response to both the first and second switch components being in ON states.

4. The MRI RF coil according to claim 1, wherein the second circuit branch is devoid of a switch component.

5. The MRI RF coil according to claim 1, further comprising:
a third circuit branch and a fourth circuit branch electrically coupled from the first RF shield to the first end ring, wherein the first, second, third, and fourth circuit branches are circumferentially spaced around the first end ring with about 90 degrees separating each circuit branch from each neighboring circuit branch.

6. The MRI RF coil according to claim 5, further comprising:
a second RF shield bordering the second end ring; and
a plurality of additional circuit branches electrically coupled from the second RF shield to the second end ring, wherein the second end ring, the second RF shield, and the plurality of additional circuit branches form a second resonant decoupling coil configured to selectively resonate at the working frequency of the birdcage coil.

7. The MRI RF coil according to claim 1, wherein the first switch component consists essentially of a diode.

8. The MRI RF coil according to claim 1, wherein the first switch component comprises a pair of anti-series diodes.

9. The MRI RF coil according to claim 1, wherein the first switch component comprises:
a series inductor-capacitor (LC) resonant circuit;
a parallel LC resonant circuit sharing a reactive element with the series LC resonant circuit; and
a diode configured to selectively toggle between a first state in which the series LC resonant circuit resonates to create a low impedance activating the first resonant decoupling coil, and a second state in which the parallel LC resonant circuit resonates to create a high impedance deactivating the first resonant decoupling coil.

10. The MRI RF coil according to claim 9, wherein the first switch component is configured for global tuning of the birdcage coil while the birdcage coil is in a resonant mode.

11. The MRI RF coil according to claim 1, wherein the first RF shield corresponds to a ring-shaped structure bordering the first end ring.

12. The MRI RF coil according to claim 1, wherein the first RF shield corresponds to a conductive tube surrounding the birdcage coil.

13. The MRI RF coil according to claim 1, wherein the first RF shield corresponds to a birdcage structure surrounding the birdcage coil.

14. A magnetic resonance imaging (MRI) system, comprising:
an MRI radio frequency (RF) coil, comprising:
a birdcage coil comprising a first end ring, a second end ring, and a plurality of rungs extending from the first end ring to the second end ring; and
a decoupling coil sharing the first end ring with the birdcage coil and comprising:
a first RF shield; and
a plurality of circuit branches electrically coupled from the first RF shield to the first end ring and comprising a first circuit branch, which comprises a first switch component;
an RF circuit electrically coupled to the birdcage coil; and
a control computer electrically coupled to the first switch component and configured to control the first switch component to change the decoupling coil between a resonant mode and a non-resonant mode, wherein the resonant mode decouples the birdcage coil.

15. The MRI system according to claim 14, wherein the decoupling coil has a total of one switch component and a total of two circuit branches electrically coupled from the first end ring to the first RF shield.

16. The MRI system according to claim 14, wherein the decoupling coil has a total of two switch components and a total of two or four circuit branches electrically coupled from the first end ring to the first RF shield.

17. The MRI system according to claim 14, wherein the decoupling coil has a total of four switch components and a total of four circuit branches electrically coupled from the first end ring to the first RF shield.

18. The MRI system according to claim 17, wherein the decoupling coil is configured to decouple the birdcage coil from multiple directions that are orthogonal to each other and to an axis of the birdcage coil around which the first and second end rings extend circumferentially.

19. The MRI system according to claim 14, wherein the first switch component has a first state that decouples the birdcage coil while the first switch component is electrically controlled, a second state that enables resonance of the birdcage coil while the first switch component is electrically controlled, and a third state that decouples the birdcage coil while the first switch component is electrically disconnected.

20. A method, comprising:
providing a radio frequency (RF) coil that comprises a birdcage coil, a first RF shield bordering a first end ring of the birdcage coil, and a plurality of circuit branches electrically coupled from the first end ring to the first RF shield, wherein a first circuit branch of the plurality of circuit branches comprises a first switch component, and wherein the plurality of circuit branches, the first end ring, and the first RF shield form a decoupling coil;
performing magnetic resonance imaging (MRI) on a scan object to generate an image of the scan object using the birdcage coil as a transmit coil and/or a receive coil; and
controlling the first switch component while performing the MRI to change the decoupling coil between a resonant mode and a non-resonant mode, wherein the resonant mode resonates at the same resonant frequency as the birdcage coil and decouples the birdcage coil.
